(19) United States
(12) Patent Application Publication
(10) Pub. No.: US 2017/0338219 A1
(43) Pub. Date: Nov. 23, 2017

(54) SEMICONDUCTOR INTEGRATED CIRCUIT DEVICE INCLUDING AN ELECTROSTATIC DISCHARGE PROTECTION CIRCUIT

(71) Applicant: SK hynix Inc., Icheon-si Gyeonggi-do (KR)

(72) Inventors: Joung Cheul CHOI, Icheon-si Gyeonggi-do (KR); Jin Woo KIM, Icheon-si Gyeonggi-do (KR)

(21) Appl. No.: 15/363,221

(22) Filed: Nov. 29, 2016

(30) Foreign Application Priority Data
May 23, 2016 (KR) 10-2016-0062689

(51) Int. Cl. H01L 27/02; H01L 23/528

(52) U.S. Cl. CPC H01L 27/0255; H01L 23/5286

(57) ABSTRACT

A semiconductor integrated circuit device having a first clamping circuit, a second clamping circuit, a third clamping circuit, a first path-changing line and a second path-changing line. The first clamping circuit may be connected between an input/output pad and a power pad. The first clamping circuit may include a plurality of diodes serially connected with each other. The second clamping circuit may be connected between the input/output pad and a ground pad. The second clamping circuit may include a plurality of diodes serially connected with each other. The third clamping circuit may be connected between the power pad and the ground pad. The third clamping circuit may include a plurality of diodes serially connected with each other. First and second path-changing lines may be configured to direct static electricity paths.

### CROSS-REFERENCES TO RELATED APPLICATION

The present application claims priority under 35 U.S.C. §119(a) to Korean application number 10-2016-0062689, filed on May 23, 2016, in the Korean Intellectual Property Office, which is incorporated herein by reference in its entirety as though fully set forth herein.

### BACKGROUND

### 1. Technical Field

The present invention relates generally to a semiconductor integrated circuit device and in particular to a semiconductor integrated circuit device including an electrostatic discharge protection circuit.

### 2. Related Art

Generally, an electrostatic discharge (ESD) protection device prevents destruction or degradation of a product that may be caused by static electricity. When a semiconductor circuit makes contact with a charged human body or a charged apparatus, static electricity from the human body or the apparatus may be discharged into the semiconductor circuit through an external pin and an input/output pad of the semiconductor circuit. High-energy static electricity may damage the semiconductor circuit. Further, the static electricity in the semiconductor circuit may be discharged through the apparatus, causing damage to the semiconductor circuit.

In order to protect the semiconductor circuit from the static electricity, an ESD protection circuit may be employed.

### SUMMARY

In an embodiment in accordance with the present invention, a semiconductor integrated circuit device includes a first clamping circuit, a second clamping circuit, a third clamping circuit, a first path-changing line, and a second path-changing line. The first clamping circuit may be connected between an input/output pad and a power pad. The first clamping circuit may include a plurality of diodes serially connected with each other. The second clamping circuit may be connected between the input/output pad and a ground pad. The second clamping circuit may include a plurality of diodes serially connected with each other. The third clamping circuit may be connected between the power pad and the ground pad. The third clamping circuit may include a plurality of diodes serially connected with each other. The first path-changing line may be configured to direct a path of a static electricity to the third clamping circuit through the first clamping circuit when the static electricity may be discharged from the input/output pad to the ground pad. The second path-changing line may be configured to direct a path of a static electricity to the second clamping circuit through the third clamping circuit when the static electricity may be discharged from the power pad to the input/output pad.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a circuit diagram illustrating a semiconductor integrated circuit device including an ESD protection circuit in accordance with the present invention;

FIG. 2 is a circuit diagram illustrating various type ESD stress modes in accordance with the present invention;

FIG. 3 is a cross-sectional view illustrating a diode having a junction region shape in accordance with the present invention;

FIG. 4 is a circuit diagram illustrating a parasitic capacitor in a third clamping circuit in accordance with the present invention;

FIG. 5 is a circuit diagram illustrating a parasitic diode in a third clamping circuit in accordance with the present invention;

FIG. 6 is a circuit diagram illustrating a parasitic diode and a parasitic capacitor in an ESD protection circuit in accordance with the present invention;

FIG. 7 is a circuit diagram illustrating a semiconductor integrated circuit device including an ESD protection circuit in accordance with the present invention; and

FIG. 8 is a block diagram illustrating a memory card including a semiconductor integrated circuit device in accordance with the present invention.

### DETAILED DESCRIPTION

Hereinafter, embodiments in accordance with the present invention will be explained in more detail with reference to the accompanying drawings. Although the present invention is described with reference to a number of example embodiments thereof, it should be understood that numerous other modifications and variations may be devised by one skilled in the art that will fall within the spirit and scope of the invention. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “under,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “under” other elements or features would then be connected “above” the other elements or features. Thus, the example of the term “below” can encompass both an orientation of above and below. The device may be otherwise connected (rotated 90 degrees or at other orientations) and the spatially relative descriptors used herein interpreted accordingly.

As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art, and will not be interpreted in an idealized or overly formal sense unless expressly so defined herein.

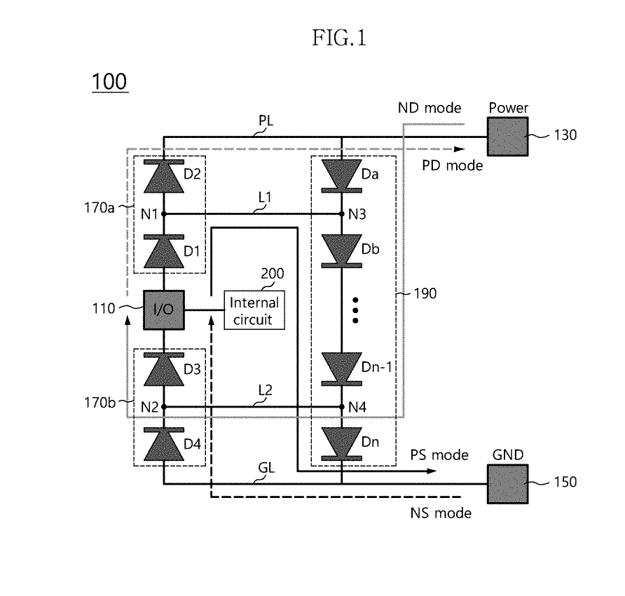

FIG. 1 illustrates a semiconductor integrated circuit device including an electrostatic discharge (ESD) protection circuit 100. The semiconductor integrated circuit of this example embodiment may include an input/output pad 110, a power pad 130, a ground pad 150, a first clamping circuit 170a, a second clamping circuit 170b, a third clamping circuit 190, an internal circuit 200, a first path-changing line L1 and a second path-changing line L2.

The input/output pad 110 may be configured to receive an external signal. The power pad 130 may be configured to receive a power voltage VDD. The ground pad 150 may be configured to receive a ground voltage.

The first clamping circuit 170a may be connected between the input/output pad 110 and the power pad 130. The first clamping circuit 170a may include first and second diodes D1 and D2. The first and second diodes D1 and D2 in the first clamping circuit 170a may be serially connected with each other between the input/output pad 110 and the power pad 130. A first node N1 may be positioned between the first diode D1 and the second diode D2. Each of the first and second diodes D1 and D2 may include an anode connected toward the input/output pad 110 and a cathode connected toward the power pad 130.

The second clamping circuit 170b may be connected between the input/output pad 110 and the ground pad 150. The second clamping circuit 170b may include third and fourth diodes D3 and D4. The third and fourth diodes D3 and D4 in the second clamping circuit 170b may be serially connected with each other between the input/output pad 110 and the ground pad 150. A second node N2 may be positioned between the third diode D3 and the fourth diode D4. Each of the third and fourth diodes D3 and D4 may include an anode connected toward the ground pad 150 and a cathode connected toward the input/output pad 110.

The third clamping circuit 190 may be connected between the power pad 130 and the ground pad 150. The third clamping circuit 190 may include a plurality of diodes Da to Dn serially connected with each other. The number of diodes Da to Dn in the third clamping circuit 190 may be determined in accordance with a difference between a voltage applied from the power pad 130 and a voltage applied from the ground pad 150. Each of the diodes Da to Dn may include an anode connected toward the power pad 130 and a cathode connected toward the ground pad 150. The diodes Da to Dn in the third clamping circuit 190 may connected in parallel, although configured in opposite polarity, with the first to fourth diodes D1, D2, D3 and D4 in the first and second clamping circuits 170a and 170b. By opposite polarity, it is meant that the anodes and cathodes of diodes Da to Dn are arranged in opposite directions to the anodes and cathodes of diodes D1 through D4. A third node N3 may be positioned between the first diode Da and the second diode Db of the third clamping circuit 190. A fourth node N4 may be positioned between the nth diode Dn and the (n−1)th diode Dn−1 of the third clamping circuit 190. For example, the first diode Da may be directly connected with the power pad 130 and the nth diode Dn may be directly connected with the ground pad 150.

All of the diodes in the first to third clamping circuits 170a, 170n and 190 may be junction type diodes. Alternatively, one or more of the diodes in the first to third clamping circuits 170a, 170b and 190 may be gate-coupled NMOS (GCNMOS) types or gate-grounded NMOS (GGNMOS) types.

The first path-changing line L1 may include a conductive line connected between the first node N1 and the third node N3. The second path-changing line L2 may include a conductive line connected between the second node N2 and the fourth node N4.

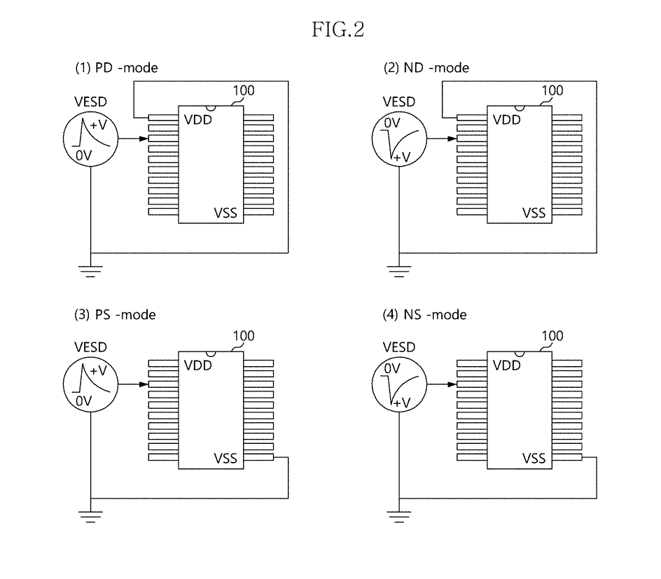

A general semiconductor integrated circuit device may have various ESD stress modes. For example, as shown in FIG. 2, the ESD stress modes may include (1) a pin to VDD positive (PD) mode, (2) a pin to VDD negative (ND) mode, (3) a pin to VSS positive (PS) mode, and (4) a pin to VSS negative (NS) mode.

A current flow in the PD mode may correspond to a static electricity flow from the input/output pad 110 to the power pad 130. A positive static electricity flowing from the input/output pad 110 may be discharged to the power pad 130 through the diodes D1 and D2 in the first clamping circuit 170a and a power voltage line PL. The diodes D1 and D2 in the first clamping circuit 170a may be forwardly connected along the static electricity flow in the PD mode. Thus, the positive static electricity flowing from the input/output pad 110 may be effectively bypassed by the diodes D1 and D2 connected in the forward direction.

A current flow in the ND mode may correspond to a static electricity flow from power pad 130 to the input/output pad 110. A negative static electricity flowing from the power pad 130 may be bypassed along the second path-changing line L2 through the first to (n−1)th diodes Da to Dn−1 in the third clamping circuit 190. The bypassed negative static electricity may be discharged to the input/output pad 110 through the third diode D3 in the second clamping circuit 170b. The diodes Da to Dn−1 in the third clamping circuit 190 and the third diode D3 in the second clamping circuit 170b may be forwardly connected along the static electricity flow in the ND mode. Thus, the negative static electricity flowing from the power pad 130 may be effectively bypassed by the diodes Da to Dn−1 and D3 connected in the forward direction and the second path-changing line L2.

A current flow in the PS mode may correspond to a static electricity flow from the input/output pad 110 to the ground pad 150. A positive static electricity flowing from the input/output pad 110 may be discharged to the ground pad 150 through the first diode D1 in the first clamping circuit 170a, the first path-changing line L1 and the second to (n−1)th diode Db to Dn−1 in the third clamping circuit 190. The first diode D1 in the first clamping circuit 190 and the second to (n−1)th diodes Db to Dn−1 in the third clamping circuit 190 may be forwardly connected along the static electricity flow in the PS mode. Thus, the positive static electricity flowing from the input/output pad 110 may be effectively bypassed by the diodes D1 and Db to Dn−1 connected in the forward direction.

A current flow in the NS mode may correspond to a static electricity flow from ground pad 150 to the input/output pad 110. A negative static electricity flowing from the ground pad 150 may be discharged to the input/output pad 110 through a ground voltage line GL and the fourth and third diodes D4 and D3 in the second clamping circuit 170b. The fourth and third diodes D4 and D3 in the second clamping circuit 170b may be forwardly connected along the static electricity flow in the NS mode. Thus, the negative static electricity flowing from the ground pad 150 may be effectively bypassed by the fourth and third diodes D4 and D3 connected in the forward direction.

As mentioned above, the ESD protection circuit 100 may include the third clamping circuit 190 having the serial diodes between the power pad 130 and the ground pad 150. Therefore, the ESD protection circuit 100 may stably discharge the static electricity in the event that a metal line affected by an integration density may be connected between the power pad 130 and the ground pad 150. Particularly, when the metal line may be connected between the power pad 130 and the ground pad 150, a width of the metal line may be restricted due to the integration density. Thus, the metal line may have a high resistance that may affect operation of an ESD protection circuit. In contrast, when the ESD protection circuit 100 may include the forward diodes, a discharge efficiency of the ESD discharge path per an area may be improved so that the ESD protection circuit 100 may be integrated in a region and a peripheral region of the input/output pad 110. As a result, a voltage increase caused by the resistance of the metal line on the ESD discharge path may be reduced so that the internal circuit 200 may be effectively protected in the ESD discharge.

The ESD protection circuit 100 may include the first path-changing line L1. The first path-changing line L1 may be connected between the first node N1 in the first clamping circuit 170a and the third node N3 in the third clamping circuit 190. The ESD protection circuit 100 may include the second path-changing line L2. The second path-changing line L2 may be connected between the second node N1 in the second clamping circuit 170b and the fourth node N4 in the third clamping circuit 190. The static electricity of the stress modes may be discharged through the forward diodes by the first path-changing line L1 and the second path-changing line L2.

A driving voltage of the ESD protection circuit may be proportional to the number of forward diodes in the discharge path. Although the semiconductor integrated circuit device may be operated at a low voltage, the ESD protection circuit of the example embodiment may still achieve the appropriate driving voltage, in accordance with the number of serially connected diodes, for provision to the ESD protection circuit.

A following formula may indicate a total driving voltage of the ESD protection circuit.

Vfon_tot=Vfon×n

Vfon_tot may indicate the total driving voltage of the ESD protection circuit. Vfon may indicate a driving voltage of the diode and n may indicate number of diodes.

The static electricity may pass through the forward diodes on the static electricity path so that a driving voltage of the ESD protection circuit increases by a voltage corresponding to the number of forward diodes multiplied by the driving voltage of the semiconductor integrated circuit device in the PS mode and the ND mode.

When the diodes in the first to third clamping circuits 170a, 170b and 190 are junction-type diodes, the layout area may be reduced compared to the case where the diodes include one or more MOS-transistor types.

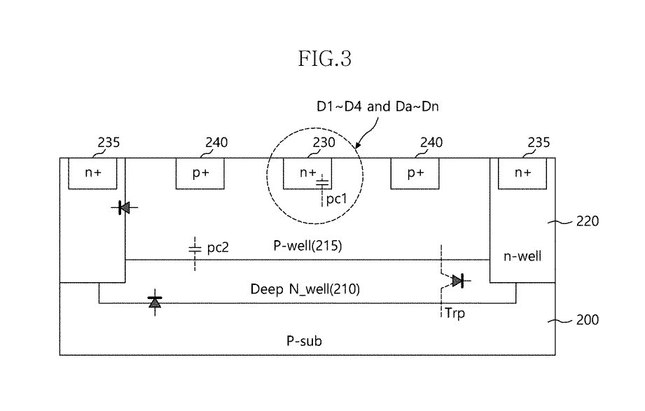

FIG. 3 illustrates a method of manufacturing a junction-type diode. First, a semiconductor substrate 200 may be prepared. The semiconductor substrate 200 may include a P type silicon substrate. N type impurities may be implanted into the semiconductor substrate 200 to form an N well 210 in the semiconductor substrate 200. P type impurities may be implanted into an upper portion of the N well 210 to form a P well 215. An N well 220 may be partially formed in the P well 215 to define an active region. The N well 220 may be configured to surround the P well 215 to define the active region in the P well 215 surrounded by the N well 220. Thus, the P well 215 as the active region may be divided by the N well 220 and the N well 210.

N type impurity regions 230 and 235 may be formed in the P well 215 and the N well 235. The N type impurity region 230 in the P well 215 may be junction diodes D1 to D4 and Da to Dn by the junction of the P well 215. The N type impurity region 235 in the N well 220 may be an N well contact region for providing an electrical signal to the N well 220.

At least one P type impurity region 240 may be formed in the P well 215. The P type impurity region 240 may be operated as a P well contact region for providing an electrical signal to the P well 215.

The first to third clamping circuits 170a, 170b and 190 of this example embodiment may include serially arranged diodes in accordance with the structure illustrated in FIG. 3.

When manufacturing the junction diodes D1 to D4 and Da to Dn, parasitic elements as well as the junction diodes D1 to D4 and Da to Dn may be generated.

For example, a junction capacitor Pc1 may be generated between the N type impurity region 230 in the junction diodes D1 to D4 and Da to Dn and the P well 215. A junction capacitor Pct may be generated between the P well 215 and the deep N well 210. Parasitic diodes Dp1 and Dp2 and a parasitic bipolar transistor Trp may be generated in other junction regions.

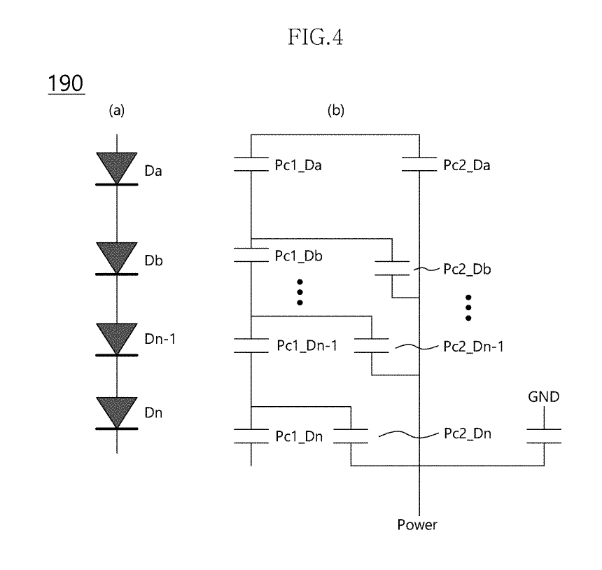

In FIG. 4, (a) may indicate the junction diodes Da to Dn serially connected with each other, and (b) may indicated parasitic capacitors Pc1_Da to Pc2_Dn generated in the junction diodes Da to Dn.

As mentioned above, first junction capacitors Pc1_Da to Pc1_Dn may be generated between the P well 215 including the junction diodes Da to Dn and the N type impurity region 230. Because the first junction capacitors Pc1_Da to Pc1_Dn may be serially connected with each other in a fashion similar to the junction diodes Da to Dn, an effective parasitic capacitance may be decreased.

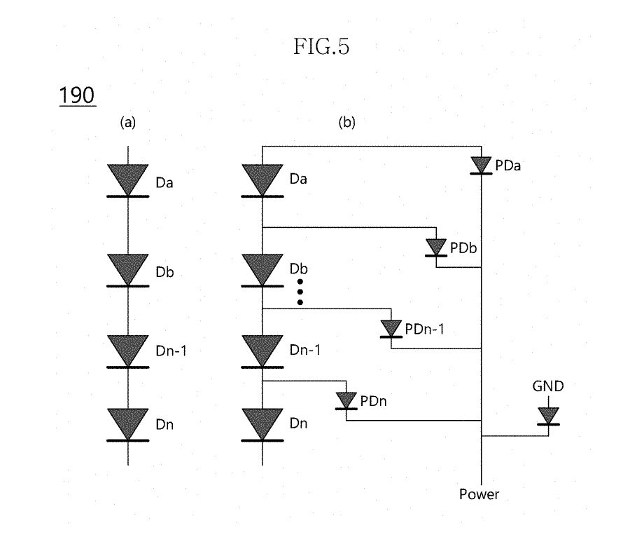

In FIG. 5, (a) may indicate the junction diodes Da to Dn serially connected with each other, and (b) may indicated parasitic diodes PDa to PDn generated in the junction diodes Da to Dn.

The junction diodes Da to Dn may be generated at a PN junction region, for example, between the P well 215 and the N well 220. However, the parasitic diodes PDa to PDn, as well as the junction diodes Da to Dn, may be generated between the semiconductor substrate 200 and the deep N well 210. The parasitic diodes PDa to PDn may be parallely connected with the junction diodes Da to Dn. The parasitic diodes PDa to PDn may discharge the static electricity from the ground pad 150 to the input/output pad 110 or to the power pad 130 together with the junction diodes Da to Dn.

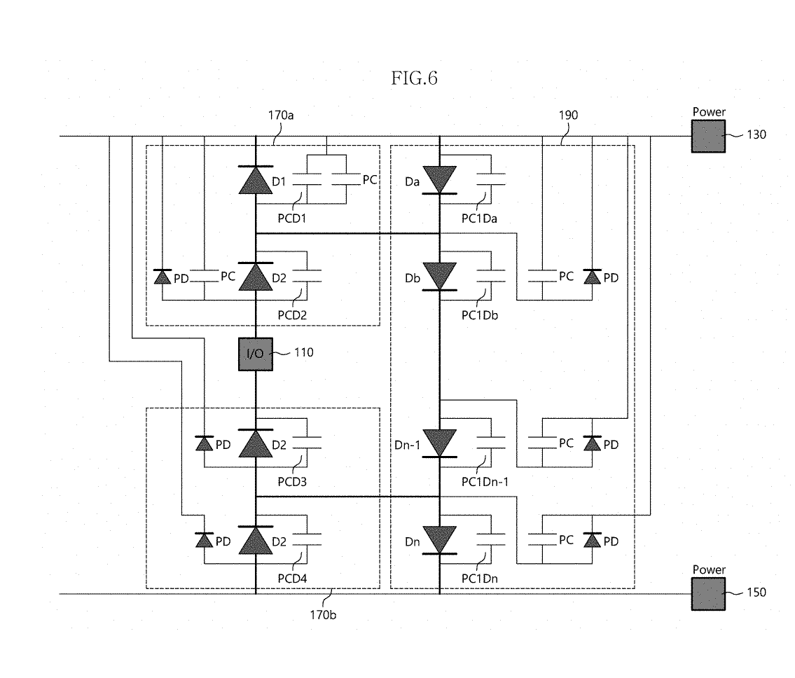

FIG. 6 indicates that the parasitic diodes and the parasitic capacitors may be generated in the junction diodes. The ESD protection circuit of this example embodiment may include the first junction capacitors PcD1 to PcD4 and Pc1_Da to Pc1_Dn having a high capacitance serially connected with each other so that a junction capacitance may be decreased when the power voltage or the ground voltage is applied to the input/output pad 110. The ESD protection circuit of this example embodiment may be integrated in a peripheral region of the input/output pad 110 for requiring a high speed to reduce the capacitance of the input/output pad 110 so that the semiconductor integrated circuit device may have a rapid operational speed.

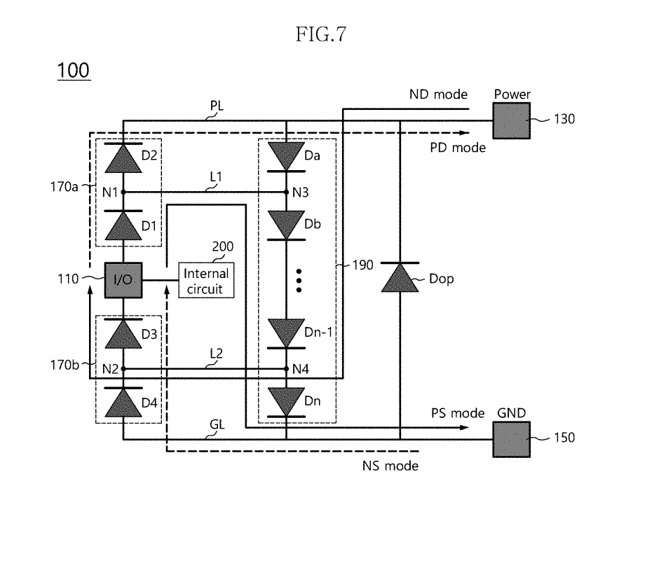

FIG. 7 depicts an additional diode Dop that may be connected between the power pad 130 and the ground pad 150. The diode Dop may be connected in a forward direction with respect to the current direction from the ground pad 150 to the power pad 130. As a result, the diode Dop may be connected in parallel with the diodes Da to Dn in the third clamping circuit 190, although configured in opposite polarity.

By connecting the diode Dop, the number of forward diodes configured to discharge the static electricity may be substantially decreased in the ND mode or the PS mode, when the static electricity may be introduced. Thus, although the driving voltage applied to the input/output pad 110 may be decreased, voltage stresses of the internal circuit 200 may be reduced when the static electricity is discharged.

According to example embodiments, the forward diodes on the discharge path of the static electricity may be serially connected with each other to secure the operational voltage of the ESD protection circuit. Further, the forward diodes in the ESD protection circuit may have the junction diodes shape to secure a sufficient layout area.

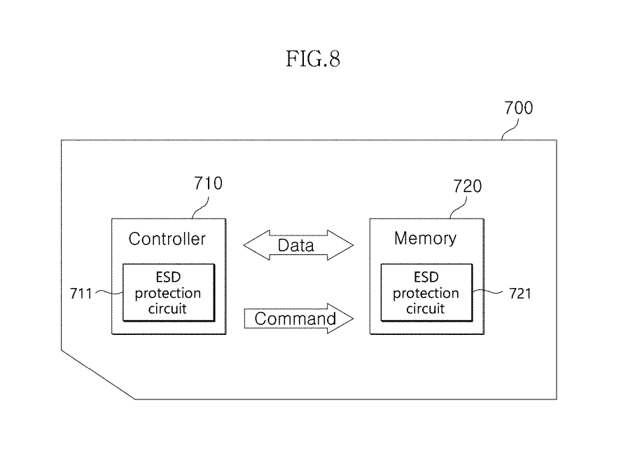

FIG. 8 illustrates a memory card 700 that may include a controller 710 and a memory 720. The controller 710 and the memory 720 may include the semiconductor integrated circuit device of example embodiments. The semiconductor integrated circuit device in the controller 710 and the memory 720 may include the ESD protection circuits 711 and 721 of example embodiments.

The controller 710 or the memory may include at least one pad. The ESD protection circuit of example embodiments may be connected between the pads to effectively discharge the static electricity.

The memory card 700 may include a memory stick card, a smart media card (SM), a secure digital card (SD), a mini-secure digital card (mini-SD), a multi-media card (NMC), etc.

While certain embodiments have been described above, it will be understood by those skilled in the art that the embodiments described are by way of example only. Accordingly, the electrostatic protection features described herein should not be limited based on the described embodiments. Rather, the electrostatic protection features described herein should only be limited in light of the claims that follow, when taken in conjunction with the above description and accompanying drawings.

What is claimed is:

1. A semiconductor integrated circuit device comprising:
a first clamping circuit connected between an input/output pad and a power pad, the first clamping circuit including a plurality of diodes serially connected with each other;
a second clamping circuit connected between the input/output pad and a ground pad, the second clamping circuit including a plurality of diodes serially connected with each other;
a third clamping circuit connected between the power pad and the ground pad, the third clamping circuit including a plurality of diodes serially connected with each other;
a first path-changing line configured to direct a static electricity to the third clamping circuit through the first clamping circuit when the static electricity is discharged from the input/output pad to the ground pad; and
a second path-changing line configured to direct a static electricity to the second clamping circuit through the third clamping circuit when the static electricity is discharged from the power pad to the input/output pad.

2. The semiconductor integrated circuit device of claim 1, wherein the diodes in the first to third clamping circuits are connected in a forward direction with respect to a flow direction of the static electricity.

3. The semiconductor integrated circuit device of claim 1, wherein the diodes in the first to third clamping circuits comprise junction diodes.

4. The semiconductor integrated circuit device of claim 1, further comprising a diode connected between the power pad and the ground pad, the diode connected in parallel and in opposite polarity with the diodes in the third clamping circuit.

5. The semiconductor integrated circuit device of claim 1, wherein the first path-changing line comprises a conductive line connected with a node selected from a node between the diodes in the first clamping circuit and a node between the diodes in the third clamping circuit.

6. The semiconductor integrated circuit device of claim 1, wherein the second path-changing line comprises a conductive line connected with a node selected from a node between the diodes in the second clamping circuit and a node between the diodes in the third clamping circuit.

7. A semiconductor integrated circuit device comprising:
a first clamping circuit connected between an input/output pad and a power pad, the first clamping circuit including a plurality of diodes serially connected with each other;
a second clamping circuit connected between the input/output pad and a ground pad, the second clamping circuit including a plurality of diodes serially connected with each other; and
a third clamping circuit connected between the power pad and the ground pad, the third clamping circuit including a plurality of diodes serially connected with each other,
wherein the diodes in the first clamping circuit are connected in a forward direction with respect to a flow direction of a static electricity when the static electricity is discharged from the input/output pad to the power pad.

8. The semiconductor integrated circuit device of claim 7, wherein the diodes in the second clamping circuit are connected in a forward direction with respect to the flow direction of the static electricity when the static electricity is discharged from the ground pad to the input/output pad.

9. The semiconductor integrated circuit device of claim 8, wherein the diodes in the third clamping circuit are connected in a forward direction with respect to flow directions of the static electricity when the static electricity is discharged from the input/output pad to the ground pad and from the power pad to the input/output pad.

10. The semiconductor integrated circuit device of claim 7, further comprising:
a first path-changing line connected between a node in the first clamping circuit and a first node in the third clamping circuit; and
a second path-changing line connected between a node in the second clamping circuit and a second node in the third clamping circuit.

11. The semiconductor integrated circuit device of claim 10, wherein the node in the first clamping circuit comprises any one of nodes connected between the diodes in the first clamping circuit,
the node in the second clamping circuit comprises any one of nodes connected between the diodes in the second clamping circuit,
the first node in the third clamping circuit comprises a node connected between a first diode and a second diode in the third clamping circuit, and the second node in the third clamping circuit comprises a node connected between an (n−1)th diode and an nth diode in the third clamping circuit.

12. The semiconductor integrated circuit device of claim 7, further comprising a diode connected between the power pad and the ground pad, the diode connected in parallel and in opposite polarity with the diodes in the third clamping circuit.

13. The semiconductor integrated circuit device of claim 7, wherein the diodes in the first to third clamping circuits comprise junction diodes.

14. The semiconductor integrated circuit device of claim 7, wherein one or more of the diodes in the first to third clamping circuits comprises junction diodes, and remaining diodes in the first to third clamping circuits comprise gate-coupled NMOS (GCNMOS) or gate-grounded NMOS (GGNMOS).

15. A semiconductor memory system having controller circuitry and memory circuitry that includes at least one input/output pad and at least one power pad, the semiconductor memory device further comprising:
a first clamping circuit connected between an input/output pad and a power pad, the first clamping circuit including a plurality of diodes serially connected with each other;
a second clamping circuit connected between the input/output pad and a ground pad, the second clamping circuit including a plurality of diodes serially connected with each other;
a third clamping circuit connected between the power pad and the ground pad, the third clamping circuit including a plurality of diodes serially connected with each other;
a first path-changing line configured to direct a static electricity to the third clamping circuit through the first clamping circuit when the static electricity is discharged from the input/output pad to the ground pad; and
a second path-changing line configured to direct a static electricity to the second clamping circuit through the third clamping circuit when the static electricity is discharged from the power pad to the input/output pad.
